(19) United States
(12) Patent Application Publication
(10) Pub. No.: US 2025/0221263 A1
(43) Pub. Date: Jul. 3, 2025

(54) DISPLAY DEVICE

(71) Applicant: LG Display Co., Ltd., Seoul (KR)

(72) Inventors: Hanseok LEE, Paju-si (KR); JoonYoung HEO, Paju-si (KR)

(21) Appl. No.: 18/929,211

(22) Filed: Oct. 28, 2024

(30) Foreign Application Priority Data
Dec. 29, 2023 (KR) 10-2023-0196026

(51) Int. Cl. H10K 59/80; H10K 59/12; H10K 59/122

(52) U.S. Cl. CPC H10K 59/873; H10K 59/122; H10K 59/80521; H10K 59/1201

(57) ABSTRACT

A display device includes a base substrate including a display area and a non-display area which surrounds the display area. The device includes a planarization layer over the base substrate, a plurality of first electrodes over the planarization layer. The device includes at least one sacrificial layer over the first electrode in the non-display area. The device includes a bank layer covering an end of the first electrode disposed in the display area and over the sacrificial layer which is disposed in the non-display area. The device includes a light emitting layer over the first electrode and the bank layer which is over the sacrificial layer. The device includes a second electrode over the light emitting layer. The light emitting layer which is over the sacrificial layer is disconnected from the light emitting layer which is disposed in the display area.

### CROSS-REFERENCE TO RELATED APPLICATION

This application claims priority from Korean Patent Application No. 10-2023-0196026 filed on Dec. 29, 2023, which is hereby incorporated by reference for all purposes as if fully set forth herein.

### BACKGROUND

### Technical Field

Embodiments of the present disclosure relate to a display device.

### Description of the Related Art

As the information age is entered, the field of displays which visually express electrical information signals has developed rapidly, and in response to this, various display devices with excellent performance such as thinness, light weight and low power consumption are being developed.

Specific examples of such display devices include a liquid crystal display device (LCD), a plasma display panel device (PDP), a field emission display device (FED), an organic light emitting display device (OLED), and so on.

Recently, research is being actively conducted to provide a larger display area in a display device. That is to say, research is being actively conducted on narrow bezel technology for providing a wider and larger image to users by minimizing an edge part where an image is not outputted and increasing a part where an image is outputted.

### BRIEF SUMMARY

In general, a display device may include, in order to protect a light emitting element from external moisture and oxygen, an encapsulation layer made of an organic material and a protective layer made of an inorganic material. Previously, both the encapsulation layer and the protective layer cover both the top and the side of the light emitting element to improve moisture penetration resistance, but recently, in order to implement a narrow bezel, the encapsulation layer is formed to cover only the top of the light emitting element. That is to say, as the encapsulation layer which is made of an organic material and is thus relatively thick covers only the top of the light emitting element and the protective layer which is made of an inorganic material thinner than an organic material covers the top and the side of the light emitting element, a narrow bezel is implemented.

However, although such a structure may implement a narrow bezel, a problem arises in that, since it is difficult to effectively block moisture introduced through the side of a bezel area, moisture penetration resistance deteriorates. Accordingly, when moisture is introduced through the side of the bezel area, a problem arises in that introduced moisture flows into the end of the light emitting element made of an organic material and thus the reliability of a display device deteriorates.

Accordingly, the inventors of the present disclosure have invented a display device capable of solving reliability deterioration due to moisture penetration, by disconnecting a light emitting clement located in a non-display area as a bezel area and thereby blocking a path through which moisture flows.

Embodiments of the present disclosure are directed to providing a display device capable of securing the reliability of the display device, by forming a sacrificial layer in a non-display area and forming a light emitting element to be disconnected on the sacrificial layer so as to block a path through which moisture flows.

Embodiments of the present disclosure are directed to providing a display device with excellent moisture penetration resistance because a moisture penetration path increases as much as the height of a sacrificial layer.

Embodiments of the present disclosure are directed to providing a display device capable of enabling implementation of a narrow bezel and having a lightweight, by forming an encapsulation layer made of an organic material to seal the inner side of a bank layer and cover only the top of a light emitting element.

According to an embodiment of the present disclosure, a display device may include: a base substrate including a display area and a non-display area which surrounds the display area; a planarization layer disposed on the base substrate; a plurality of first electrodes disposed on the planarization layer; at least one sacrificial layer disposed on the first electrode in the non-display area; a bank layer covering an end of the first electrode disposed in the display area and disposed on the sacrificial layer which is disposed in the non-display area; a light emitting layer disposed on the first electrode and the bank layer which is disposed on the sacrificial layer; and a second electrode disposed on the light emitting layer, wherein the light emitting layer which is disposed on the sacrificial layer is disconnected from the light emitting layer which is disposed in the display area.

According to an embodiment of the present disclosure, a display device may include: a base substrate including a display area and a non-display area which surrounds the display area; a planarization layer disposed on the base substrate; a plurality of first electrodes disposed on the planarization layer; at least one sacrificial layer disposed on the first electrode in the non-display area; a bank layer including a first opening which exposes the first electrode disposed in the display area and a second opening which exposes a part other than the sacrificial layer disposed in the non-display area; a light emitting layer disposed on a top of the bank layer and the first electrode and the planarization layer which are exposed through the first opening and the second opening; and a second electrode disposed on the light emitting layer, wherein the sacrificial layer is formed as a protruding structure which surrounds the display area in the non-display area, and the light emitting layer is disconnected by not being disposed on a side of the sacrificial layer.

According to the embodiments of the present disclosure, it is possible to provide a display device capable of securing the reliability of the display device, by forming a sacrificial layer in a non-display area and forming a light emitting element to be disconnected on the sacrificial layer so as to block a path through which moisture flows.

According to the embodiments of the present disclosure, it is possible to provide a display device with excellent moisture penetration resistance because a moisture penetration path increases as much as the height of a sacrificial layer.

According to the embodiments of the present disclosure, it is possible to provide a display device capable of enabling implementation of a narrow bezel and having a lightweight, by causing an encapsulation layer made of an organic material to seal the inner side of a bank layer and cover only the top of a light emitting element.

### DESCRIPTION OF THE SEVERAL VIEWS OF THE DRAWINGS

FIG. 1 is a system configuration diagram of a display device according to an embodiment of the present disclosure.

FIG. 2 is a cross-sectional view of the display device shown in FIG. 1, taken along the line A-A′.

FIGS. 3A to 3F are views illustrating a process sequence for manufacturing the display device illustrated in FIG. 2.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including,” “having,” “containing,” “constituting,” “make up of” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A)” or “(B)” may be used herein to describe elements of the present disclosure. Each of these terms is not used to define essence, order, sequence, number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,” “contact or overlap,” etc., each other.

When time relative terms, such as “after,” “subsequent to,” “next,” “before” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, etc., are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can.”

Hereinafter, various embodiments of the present disclosure will be described in detail with reference to accompanying drawings.

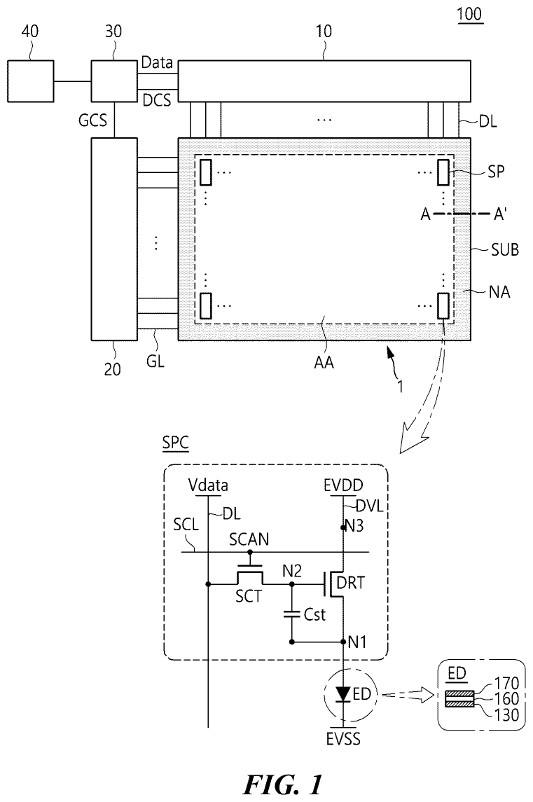

FIG. 1 is a system configuration diagram of a display device according to an embodiment of the present disclosure.

Referring to FIG. 1, the display driving system of the display device 100 according to the embodiment of the present disclosure may include a display panel 1 and a display driving circuit for driving the display panel 1.

The display panel 1 may include a display area AA in which an image is displayed and a non-display area NA in which an image is not displayed. The display panel 1 may include a plurality of subpixels SP which are disposed on a base substrate to display an image.

The display panel 1 may include a plurality of signal wirings which are disposed on the base substrate. For example, the plurality of signal wirings may include data lines DL, gate lines GL, driving voltage lines, etc.

Each of the plurality of data lines DL may be disposed to extend in a first direction (e.g., a column direction or a row direction), and each of the plurality of gate lines GL may be disposed to extend in a direction intersecting the first direction.

The display driving circuit may include a data driving circuit 10 and a gate driving circuit 20, and may further include a controller 30 for controlling the data driving circuit 10 and the gate driving circuit 20.

The data driving circuit 10 may output data signals (also referred to as data voltages) corresponding to an image signal to the plurality of data lines DL. The gate driving circuit 20 may generate gate signals and output the gate signals to the plurality of gate lines GL. The controller 30 may convert input image data inputted from an external host 40 to suit a data signal format employed in the data driving circuit 10, and may supply converted image data to the data driving circuit 10.

The data driving circuit 10 may include at least one source driver integrated circuit. For example, each source driver integrated circuit may be connected to the display panel 1 in a tape automated bonding (TAB) method, may be connected to the bonding pads of the display panel 1 in a chip-on-glass (COG) or chip-on-panel (COP) method, or may be connected to the display panel 1 by being implemented in a chip-on-film (COF) method.

The gate driving circuit 20 may be connected to the display panel 1 in a tape automated bonding (TAB) method, may be connected to the bonding pads of the display panel 1 in a COG or COP method, may be connected to the display panel 1 according to a COF method, or may be formed in the non-display area NA of the display panel 1 in a gate-in-panel (GIP) type.

A GIP circuit may be disposed at each of the left and right side parts of the non-display area NA of FIG. 1, and a plurality of pads which are connected to an external circuit and an external power source as a power supply source may be disposed at the upper part of the non-display area NA.

Referring to FIG. 1, in the display device 100 according to the embodiment of the present disclosure, each subpixel SP may include a light emitting element ED and a pixel driving circuit SPC for driving the light emitting element ED. The pixel driving circuit SPC may include a driving transistor DRT, a scan transistor SCT and a storage capacitor Cst.

The driving transistor DRT may drive the light emitting element ED by controlling current flowing to the light emitting element ED. The scan transistor SCT may transfer a data voltage Vdata to a second node N2, which is the gate node of the driving transistor DRT. The storage capacitor Cst may be configured to maintain a voltage for a predetermined period of time.

The light emitting element ED may include a first electrode 130, a second electrode 170, and a light emitting layer 160 located between the first electrode 130 and the second electrode 170. The first electrode 130 may be a pixel electrode which is involved in the formation of the light emitting element ED of each subpixel SP, and may be electrically connected to a first node NI of the driving transistor DRT. The second electrode 170 may be a common electrode which is involved in the formation of the light emitting elements ED of all subpixels SP, and may be applied with a base voltage EVSS.

For example, the light emitting element ED may be an organic light emitting diode (OLED), an inorganic-based light emitting diode (LED) or a quantum dot light emitting element which is a semiconductor crystal that emits light on its own.

The driving transistor DRT as a transistor for driving the light emitting element ED may include the first node N1, the second node N2 and a third node N3. The first node NI may be a source or drain node, and may be electrically connected to the first electrode 130 of the light emitting element ED. The second node N2 may be the gate node, and may be electrically connected to a source or drain node of the scan transistor SCT. The third node N3 may be a drain or source node, and may be electrically connected to a driving voltage line DVL which supplies a driving voltage EVDD. Hereinbelow, for the sake of convenience in explanation, it may be described as an example that the first node NI is a source node and the third node N3 is a drain node.

The scan transistor SCT may switch the connection between a data line DL and the second node N2 of the driving transistor DRT. In response to a scan signal SCAN supplied from a scan line SCL as a type of gate line GL, the scan transistor SCT may control the connection between the second node N2 of the driving transistor DRT and a corresponding data line DL among the plurality of data lines DL.

The storage capacitor Cst may be configured between the first node N1 and the second node N2 of the driving transistor DRT.

The structure of the subpixel SP shown in FIG. 1 is nothing but a mere example for explanation, and may further include at least one transistor or at least one capacitor. Each of the plurality of subpixels SP may have the same structure, and some of the plurality of subpixels SP may have a different structure. Each of the driving transistor DRT and the scan transistor SCT may be an n-type transistor or a p-type transistor.

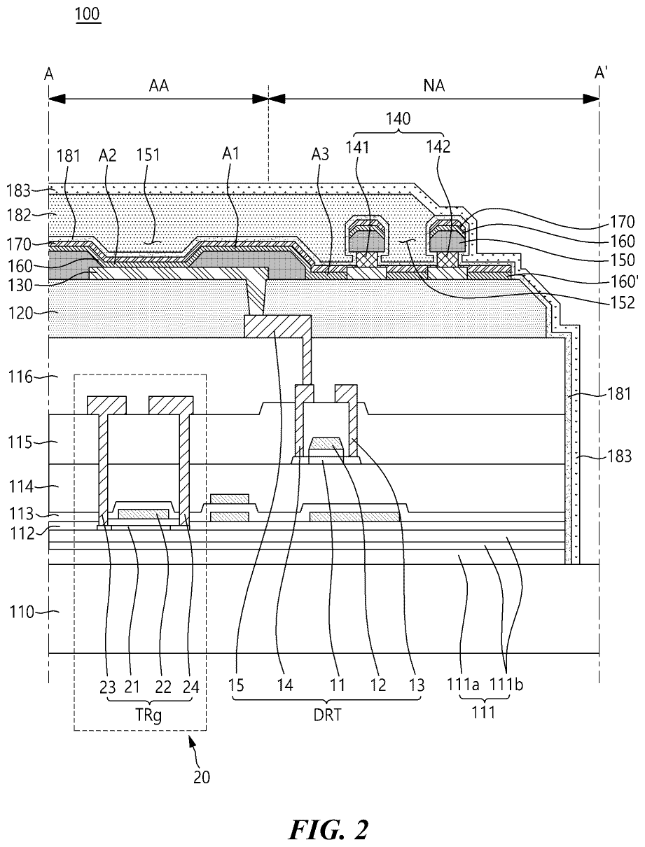

FIG. 2 is a cross-sectional view of the display device shown in FIG. 1, taken along the line A-A′.

Referring to FIG. 2, the display device 100 may include a base substrate 110, a planarization layer 120, the first electrode 130, a sacrificial layer 140, a bank layer 150, the light emitting layer 160, and the second electrode 170.

The base substrate 110 is to support various components of the display device 100, and may include the display area AA which displays an image by the plurality of subpixels SP and the non-display area NA which surrounds the display area AA. For example, the base substrate 110 may be formed of an insulating material such as polyimide (PI), glass or plastic. The non-display area NA may be formed at an edge part which forms a bezel, and the display area AA may be formed inside the edge part.

The base substrate 110 may be composed of at least two layers, and a transistor, a GIP circuit, a wiring, etc., may be disposed over the base substrate 110. For example, a first buffer layer 111, a first interlayer insulating layer 112, a gate insulating layer 113, a second buffer layer 114, a second interlayer insulating layer 115 and a planarization layer 116 may be sequentially deposited on the base substrate 110.

The first buffer layer 111 may be a single layer or a multilayer. When the first buffer layer 111 is a multilayer, the first buffer layer 111 may include a multi-buffer layer 111a and two active buffer layers 111b.

The GIP circuit 20 formed on the base substrate 110 may include a GIP type gate driving circuit TRg. In other words, the GIP circuit 20 may be one of transistors included in the GIP type gate driving circuit TRg, and may be made of, for example, low temperature polysilicon (LTPS). In the present embodiment, the GIP circuit 20 may be formed at each of both side parts of the display panel 1.

Referring to FIG. 2, the GIP circuit 20 disposed at each of both side parts of the display panel 1 is illustrated as being located in the display area AA as the inner part of the display panel 1. More specifically, the GIP circuit 20 is illustrated as being located below the first electrode 130. However, if necessary, the GIP circuit 20 may be disposed in the non-display area NA as the outer part of the display panel 1. More specifically, the GIP circuit 20 may be located below the sacrificial layer 140.

The gate driving circuit TRg may be disposed on the active buffer layer 111b, and may include an active layer 21, a gate electrode 22, a source electrode 23 and a drain electrode 24. The active layer 21 may include a channel area where a channel is formed, a source connection area on one side of the channel area, and a drain connection area on the other side of the channel area. The source electrode 23 and the drain electrode 24 may be connected to the source connection area and the drain connection area, respectively, of the active layer 21 through holes formed in the second interlayer insulating layer 115, the second buffer layer 114, the gate insulating layer 113 and the first interlayer insulating layer 112.

The planarization layer 120 is to alleviate the height differences of underlying structures, and may be disposed over the base substrate 110. For example, the planarization layer 120 may be formed of an organic material such as acrylic resin, epoxy resin, phenolic resin, polyamide resin and polyimide resin.

A plurality of first electrodes 130 may be provided to be spaced apart from each other on the planarization layer 20. For example, the first electrode 130 may be made of a transparent metallic oxide material such as indium tin oxide (ITO) or indium zinc oxide (IZO) with good conductivity. Besides, the first electrode 130 may be made of a metal material such as magnesium (Mg), calcium (Ca), sodium (Na), titanium (Ti), indium (In), yttrium (Y), lithium (Li), gadolinium (Gd), aluminum (Al), silver (Ag), tin (Sn) or lead (Pb).

The plurality of first electrodes 130 may be disposed on the planarization layer 120. For example, the first electrodes 130 may be disposed in the display area AA and the non-display area NA, and the first electrodes 130 disposed in the non-display area NA may be formed to have a structure which surrounds the display area AA. The first electrode 130 disposed in the display area AA may be electrically connected to the driving transistor DRT which is formed over the base substrate 110.

The driving transistor DRT may include an active layer 11, a gate electrode 12, a source electrode 13 and a drain electrode 14. Specifically, the first electrode 130 may be connected to the drain electrode 14 through a connection electrode 15, and the source electrode 13 and the drain electrode 14 may be connected to the active layer 11 in which a channel is formed when the driving transistor DRT is driven. The active layer 11 may be made of an oxide semiconductor.

At least one sacrificial layer 140 may be provided to be disposed on the first electrode 130 in the non-display area NA. For example, the sacrificial layer 140 may be formed as a protruding structure which is disposed along the perimeter of the display area AA in the non-display area NA.

The sacrificial layer 140 may be made of a metal or an inorganic material. For example, the sacrificial layer 140 may be made of one selected among copper (Cu), molybdenum (Mo), silicon nitride (SiNx), silicon oxide (SiOx), silicon oxynitride (SiON) and aluminum oxide (Al₂O₃).

The bank layer 150 may cover the end of the first electrode 130 disposed in the display area AA, and may be disposed on the sacrificial layer 140 which is disposed in the non-display area NA. For example, the bank layer 150 may include a first opening 151 which exposes the first electrode 130 disposed in the display area AA, and a second opening 152 which exposes a part other than the sacrificial layer 140 disposed in the non-display area NA. The bank layer 150 is to partition a pixel, and light may be outputted through the first opening 151.

The light emitting layer 160 may be disposed on a top A1 of the bank layer 150, a top A2 of the first electrode 130 exposed through the first opening 151 and the second opening 152 and a top A3 of the planarization layer 120. Namely, the light emitting layer 160 may be disposed in the display area AA and the non-display area NA, and may be disconnected by the sacrificial layer 140 in the non-display area NA. In this way, as the light emitting layer 160 is disconnected on each sacrificial layer 140, a portion 160′ of the light emitting layer 160 may be disposed between the sacrificial layer 140 disposed outermost in the non-display area NA and the end of the planarization layer 120.

When the light emitting element ED is composed of an organic light emitting diode (OLED), the light emitting layer 160 may include a hole transport layer, an organic light emitting layer, an electron transport layer, etc.

The second electrode 170 may be disposed on the light emitting layer 160. That is to say, the second electrode 170 may be formed to have the same structure as the first electrode 130, and may be disposed in the display area AA and the non-display area NA. For example, the second electrode 170 may be disposed on the top A1 of the bank layer 150, the top A2 of the first electrode 130 exposed through the first opening 151 and the second opening 152 and the top A3 of the planarization layer 120 with the light emitting layer 160 interposed therebetween. Portions of the second electrode 170 disposed on the sacrificial layer 140 may be disconnected from each other.

When voltages are applied to the first electrode 130 and the second electrode 170 which constitute the light emitting element ED, holes and electrons move to the organic light emitting layer through the hole transport layer and the electron transport layer, respectively, and combine with each other in the organic light emitting layer to emit light.

When the light emitting layer 160 is made of an organic material, the light emitting layer 160 is substantially vulnerable to moisture, and thus, it is important to improve moisture penetration resistance. To this end, the light emitting layer 160 according to the present embodiment may be disconnected in the non-display area NA by the sacrificial layer 140. For example, the light emitting layer 160 may be disconnected since the light emitting layer 160 is not disposed on the side of the sacrificial layer 140.

In this way, since the end portion of the light emitting layer 160 disposed in the non-display area NA is disconnected at an area where the sacrificial layer 140 is disposed, it is possible to prevent moisture introduced from the outside from flowing into the display area AA through the end portion of the light emitting layer 160. In other words, a path through which moisture flows may be blocked through the disconnected portion of the light emitting layer 160.

Namely, moisture likely to be introduced from the outside stays at the end portion of the light emitting layer 160 which is located over the sacrificial layer 140. In this way, by the structure proposed in the present disclosure, it is possible to block moisture from flowing into the display area AA.

Because a moisture penetration path becomes longer by the height of the sacrificial layer 140, even when moisture is introduced from the outside, a progress time may be increased. That is to say, since the light emitting layer 160 is disposed at a higher location by the height of the sacrificial layer 140, a path through which moisture flows may be lengthened by the height of the sacrificial layer 140.

The larger the height of the sacrificial layer 140 is, the longer a moisture penetration path may be. Therefore, it is desirable to form the sacrificial layer 140 to have a maximum height. However, when the height of the sacrificial layer 140 is too high, the size of the display panel 1 may increase, and thus, it is desirable to appropriately adjust the height of the sacrificial layer 140. For example, the height of the sacrificial layer 140 may be larger than the height of the first electrode 130 and smaller than the height of the bank layer 150.

In this way, in a case where a moisture penetration path for moisture to be introduced into the light emitting layer 160 through the sacrificial layer 140 is increased and a path through which moisture flows is blocked, the lifespan of the display device 100 may be increased and reliability deterioration due to moisture penetration may be solved.

The display device 100 according to the present embodiment may further include a first protective layer 181, an encapsulating layer 182 and a second protective layer 183.

The first protective layer 181 is to protect the second electrode 170 from moisture introduced from a side, and may seal the top of the second electrode 170, the sides of the sacrificial layer 140 and the bank layer 150 and the sides of the planarization layer 120 and members provided between the sacrificial layer 140 and the base substrate 110. Specifically, the first protective layer 181 may seal the sides of the first buffer layer 111, the first interlayer insulating layer 112, the gate insulating layer 113, the second buffer layer 114, the second interlayer insulating layer 115 and the planarization layer 116 which are provided on the base substrate 110. As illustrated in FIG. 2, when the sacrificial layer 140 and the bank layer 150 are disposed in the non-display area NA, the coverage area of the first protective layer 181 may increase compared to when the sacrificial layer 140 and the bank layer 150 are not disposed in the non-display area NA. Accordingly, a moisture penetration path may be increased by the first protective layer 181, which may improve the moisture penetration resistance of the display device 100 and solve reliability deterioration due to moisture penetration.

The first protective layer 181 may be formed of an inorganic insulating material capable of low-temperature deposition, such as silicon nitride (SiNx), silicon oxide (SiOx), silicon oxynitride (SiON) or aluminum oxide (Al₂O₃). In this way, when the first protective layer 181 is deposited in a low-temperature atmosphere, the first protective layer 181 may prevent the light emitting layer 160 including an organic material vulnerable to a high-temperature atmosphere from being damaged during a deposition process.

The encapsulation layer 182 may seal the inner side of the bank layer 150 on the first protective layer 181. For example, the encapsulation layer 182 may be formed of an organic insulating material such as acrylic resin, epoxy resin, polyimide, polyethylene or silicon oxycarbon (SiOC).

The end of the encapsulation layer 182 may be disposed in the second opening 152 which is formed in the bank layer 150 located in the non-display area NA. More specifically, the end of the encapsulation layer 182 which extends from the display area AA and is disposed in the non-display area NA may be blocked by the bank layer 150 located outermost. Hence, it is possible to prevent the encapsulation layer 182 from being exposed to the outside of the display device 100 or from invading a pad electrode. Since there is no need to separately install in the non-display area NA a dam to block the flow of an organic material constituting the encapsulation layer 182, a process may be simplified and a narrow bezel may be implemented.

The second protective layer 183 may seal the encapsulation layer 182 and the first protective layer 181 which is exposed out of the encapsulation layer 182. For example, the second protective layer 183 may be formed of an inorganic insulating material such as silicon nitride (SiNx), silicon oxide (SiOx), silicon oxynitride (SiON) or aluminum oxide (Al₂O₃).

According to the present embodiment, the sacrificial layer 140 may be formed to have a width smaller than the width of the bank layer 150 located on the sacrificial layer 140. Therefore, a portion of the bottom of the bank layer 150 may be exposed out of the sacrificial layer 140, and the light emitting layer 160 may be disconnected by not being disposed on the exposed portion of the bank layer 150. In other words, by forming the sacrificial layer 140 to have a width smaller than the width of the bank layer 150, during the deposition process of the light emitting layer 160, the light emitting layer 160 may be formed only on the top of the bank layer 150 and may not be formed on the sides of the sacrificial layer 140 and the bank layer 150 and the portion of the bottom of the bank layer 150 exposed out of the sacrificial layer 140. Therefore, the light emitting layer 160 may be disconnected.

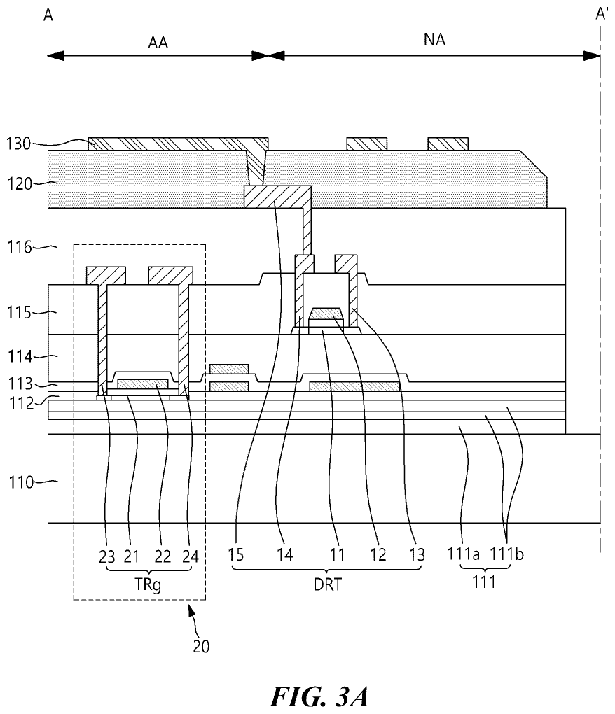

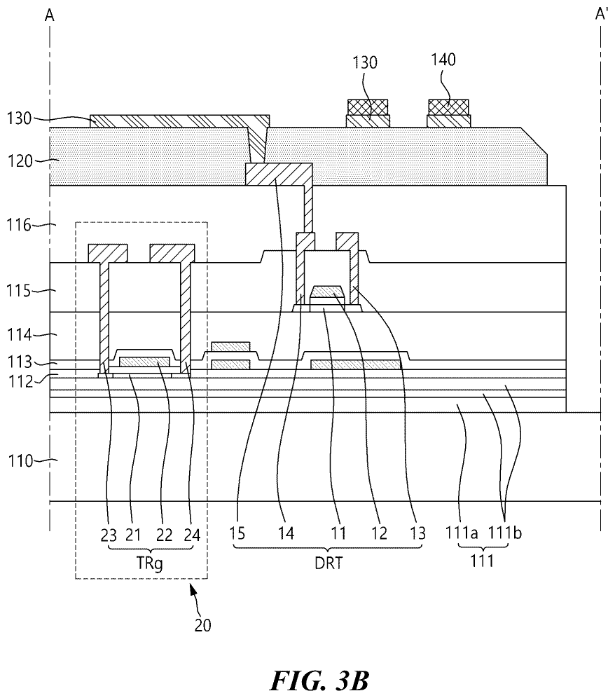

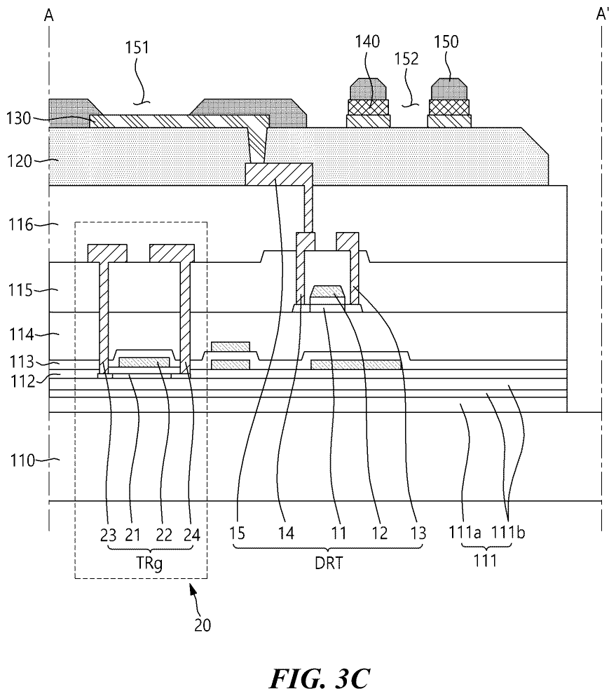

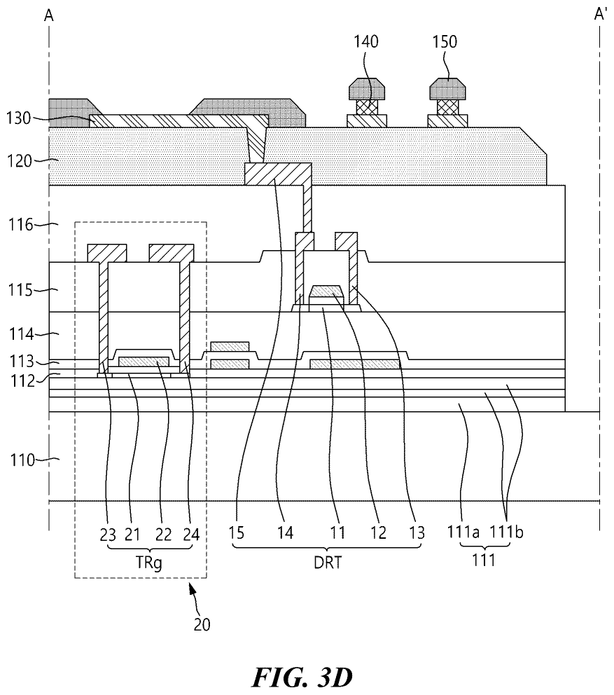

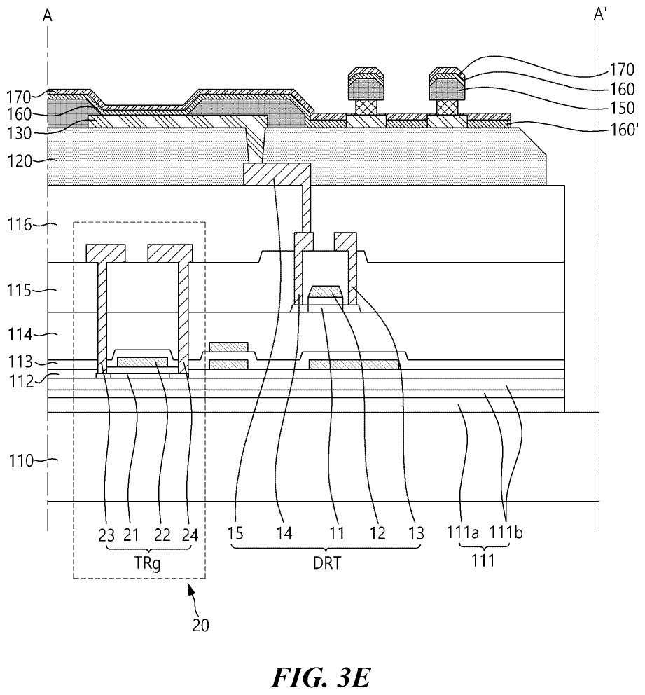

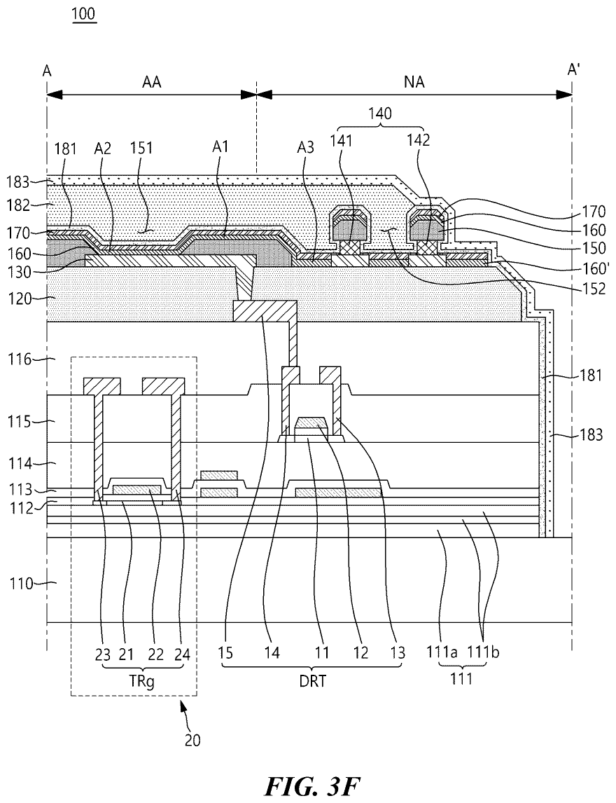

In this way, when the sacrificial layer 140 is formed to have a width smaller than the width of the bank layer 150, since a path through which moisture flows may be lengthened, moisture penetration resistance may be improved. Namely, because the bottom of the bank layer 150 is exposed out of the sacrificial layer 140 by the difference in width between the bank layer 150 and the sacrificial layer 140, a path through which moisture flows may be lengthened by the bottom area of the bank layer 150 exposed out of the sacrificial layer 140. The sacrificial layer 140 may include a first sacrificial layer 141 which is formed to surround and close the four surfaces of the display area AA in the non-display area NA, and a second sacrificial layer 142 which is formed to be spaced apart outwardly from the first sacrificial layer 141 and surround and close the four surfaces of the first sacrificial layer 141. In this way, when the plurality of sacrificial layers 141 and 142 are defined in the non-display area NA, since the number of areas where the light emitting layer 160 is disconnected increases, moisture penetration resistance may be improved. In some embodiments, a first portion of the light emitting layer 160 is on the first sacrificial layer 141 and a second portion of the light emitting layer 160 is on the second sacrificial layer 142. The first portion of the light emitting layer 160 and the second portion of the light emitting layer 160 are spaced apart from each other both from a cross-sectional view and from a plan view (see FIGS. 2 and 3F).

FIGS. 3A to 3F are views illustrating a process sequence for manufacturing the display device illustrated in FIG. 2. A process of manufacturing the display device 100 of FIG. 2 will be schematically described below with reference to FIGS. 3A to 3F.

Referring to FIG. 3A, after preparing a base substrate 110, a GIP circuit and a driving transistor DRT may be patterned on the base substrate 110, and then, a planarization layer 120 and a first electrode 130 may be formed. A plurality of first electrodes 130 may be formed in a non-display area NA to be spaced apart from each other.

As shown in FIG. 3B, a sacrificial layer 140 which is made of a metal or an inorganic material is formed on the first electrode 30 in the non-display area NA. As shown in FIG. 3C, a bank layer 150 is formed such that a first opening 151 is formed in a part corresponding to a display area AA to expose the first electrode 130 and a second opening 152 is formed in a part corresponding to the non-display area NA to expose the planarization layer 120. The bank layer 150 in the non-display area NA may be formed to have a width smaller than the width of the sacrificial layer 140 disposed thereunder, and thus, an outer edge portion of the sacrificial layer 140 may be exposed to the outside.

As shown in FIG. 3D, an etching process for the sacrificial layer 140 may be performed. The etching process may be performed as dry etching or wet etching, and a solution that selectively etches only the sacrificial layer 140 may be used. When the etching process is completed, only the side of the sacrificial layer 140 disposed between the bank layer 150 and the first electrode 130 may be etched, so that the width of the sacrificial layer 140 is smaller than the width of the bank layer 150 located thereon.

In this state, as shown in FIG. 3E, the deposition process of a light emitting layer 160 and a second electrode 170 may be performed. Due to the step between the bank layer 150 and the sacrificial layer 140, the light emitting layer 160 and the second electrode 170 are not formed on the side and the bottom of the bank layer 150 and the side of the sacrificial layer 140 during the deposition process. Accordingly, the light emitting layer 160 and the second electrode 170 may be disconnected at the side and the bottom of the bank layer 150 and the side of the sacrificial layer 140.

After the deposition process of the light emitting layer 160 and the second electrode 170 is completed in this way, as shown in FIG. 3F, the coating process of a first protective layer 181, an encapsulation layer 182 and a second protective layer 183 may be performed. For example, the first protective layer 181, the encapsulation layer 182 and the second protective layer 183 may be formed using a method such as an inkjet coating or slit coating process.

In this way, when respective processes are completed, a display device 100 in which the light emitting layer 160 and the second electrode 170 are disconnected in the non-display area NA may be implemented. Accordingly, even when moisture is introduced into the non-display area NA which forms a bezel, a path through which moisture flows to the light emitting layer 160 and the second electrode 170 located in the display area AA is blocked, whereby the reliability of the display device 100 may be secured.

Brief description of the embodiments of the present disclosure described above is as follows.

According to embodiments of the present disclosure, a display device may include a base substrate including a display area and a non-display area which surrounds the display area; a planarization layer disposed on the base substrate; a plurality of first electrodes disposed on the planarization layer; at least one sacrificial layer disposed on the first electrode in the non-display area; a bank layer covering an end of the first electrode disposed in the display area and disposed on the sacrificial layer which is disposed in the non-display area; a light emitting layer disposed on the first electrode and the bank layer which is disposed on the sacrificial layer; and a second electrode disposed on the light emitting layer, wherein the light emitting layer which is disposed on the sacrificial layer is disconnected from the light emitting layer which is disposed in the display area.

According to the embodiments of the present disclosure, the bank layer may include a first opening which exposes the first electrode disposed in the display area, and a second opening which exposes a part other than the sacrificial layer disposed in the non-display area.

According to the embodiments of the present disclosure, the second electrode which is disposed on the sacrificial layer may be disconnected from the second electrode which is disposed in the display area.

According to the embodiments of the present disclosure, portions of the light emitting layer which are disposed on sacrificial layers, respectively, may be disconnected from each other.

According to the embodiments of the present disclosure, portions of the second electrode which are disposed on sacrificial layers, respectively, may be disconnected from each other.

According to the embodiments of the present disclosure, the light emitting layer and the second electrode may be disposed between the sacrificial layer disposed outermost in the non-display area and an end of the planarization layer.

According to the embodiments of the present disclosure, the light emitting layer disposed in the non-display area may not be disposed on a side of the sacrificial layer and a side of the bank layer.

According to the embodiments of the present disclosure, a portion of a bottom of the bank layer which is disposed in the non-display area may be exposed out of the sacrificial layer, and the light emitting layer may be disconnected by being not disposed on the exposed portion of the bank layer.

According to the embodiments of the present disclosure, a width of the sacrificial layer may be formed to be smaller than a width of the bank layer located thereon.

According to the embodiments of the present disclosure, the sacrificial layer may be formed as a protruding structure which is disposed along a perimeter of the display area in the non-display area.

According to the embodiments of the present disclosure, the sacrificial layer may include a first sacrificial layer which is formed to surround and close four surfaces of the display area in the non-display area, and a second sacrificial layer which is formed to be spaced apart outwardly from the first sacrificial layer and surround and close four surfaces of the first sacrificial layer.

According to the embodiments of the present disclosure, the sacrificial layer may be made of a metal or an inorganic material.

According to the embodiments of the present disclosure, the sacrificial layer may be made of one selected among copper (Cu), molybdenum (Mo), silicon nitride (SiNx), silicon oxide (SiOx), silicon oxynitride (SiON) and aluminum oxide (Al₂O₃).

According to the embodiments of the present disclosure, a height of the sacrificial layer may be formed to be larger than a height of the first electrode and smaller than a height of the bank layer.

According to the embodiments of the present disclosure, the first electrode which is disposed in the non-display area may be formed to have a structure which surrounds the display area.

According to the embodiments of the present disclosure, the display device may further include an encapsulation layer sealing an inner side of the bank layer, and an end of the encapsulation layer may be disposed in the second opening.

According to the embodiments of the present disclosure, the display device may further include a first protective layer disposed under the encapsulation layer, and scaling a top of the second electrode, sides of the sacrificial layer and the bank layer and sides of members provided between the sacrificial layer and the base substrate.

According to the embodiments of the present disclosure, the display device may further include a second protective layer sealing the encapsulation layer and the first protective layer which is exposed out of the encapsulation layer.

According to the embodiments of the present disclosure, the first electrode disposed in the display area may be electrically connected to a driving transistor disposed thereunder.

According to embodiments of the present disclosure, a display device may include a base substrate including a display area and a non-display area which surrounds the display area; a planarization layer disposed on the base substrate; a plurality of first electrodes disposed on the planarization layer; at least one sacrificial layer disposed on the first electrode in the non-display area; a bank layer including a first opening which exposes the first electrode disposed in the display area and a second opening which exposes a part other than the sacrificial layer disposed in the non-display area; a light emitting layer disposed on a top of the bank layer and the first electrode and the planarization layer which are exposed through the first opening and the second opening; and a second electrode disposed on the light emitting layer, wherein the sacrificial layer is formed as a protruding structure which surrounds the display area in the non-display area, and the light emitting layer is disconnected by not being disposed on a side of the sacrificial layer.

According to the embodiments of the present disclosure, the light emitting layer may be disconnected by not being disposed on a side of the bank layer.

According to the embodiments of the present disclosure, a width of the sacrificial layer may be formed to be smaller than a width of the bank layer located thereon, so that a portion of a bottom of the bank layer is exposed out of the sacrificial layer, and the light emitting layer may be disconnected by not being disposed on the exposed portion of the bank layer.

According to the embodiments of the present disclosure, the display device may further include an encapsulation layer sealing an inner side of the bank layer, and an end of the encapsulation layer may be disposed in the second opening.

According to the embodiments of the present disclosure, the display device may further include a first protective layer disposed under the encapsulation layer, and sealing a top of the second electrode, sides of the sacrificial layer and the bank layer and sides of members provided between the sacrificial layer and the base substrate.

According to the embodiments of the present disclosure, the display device may further include a second protective layer sealing the encapsulation layer and the first protective layer which is exposed out of the encapsulation layer.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a base substrate including a display area and a non-display area adjacent to the display area;
a planarization layer on the base substrate;
a plurality of first electrodes on the planarization layer;
at least one sacrificial layer on the first electrode in the non-display area;
a bank layer covering an end of the first electrode disposed in the display area and on the sacrificial layer which is disposed in the non-display area;
a light emitting layer on the first electrode and the bank layer which is on the sacrificial layer; and
a second electrode on the light emitting layer,
wherein the light emitting layer which is on the sacrificial layer is disconnected from the light emitting layer which is disposed in the display area.

2. The display device of claim 1, wherein the bank layer includes a first opening which exposes the first electrode disposed in the display area, and a second opening which exposes a part other than the sacrificial layer disposed in the non-display area.

3. The display device of claim 1, wherein the second electrode which is disposed on the sacrificial layer is disconnected from the second electrode which is disposed in the display area.

4. The display device of claim 1, wherein portions of the light emitting layer which are disposed on sacrificial layers, respectively, are disconnected from each other.

5. The display device of claim 1, wherein portions of the second electrode which are disposed on sacrificial layers, respectively, are disconnected from each other.

6. The display device of claim 1, wherein the light emitting layer and the second electrode are disposed between the sacrificial layer disposed outermost in the non-display area and an end of the planarization layer.

7. The display device of claim 1, wherein the light emitting layer disposed in the non-display area is not disposed on a side of the sacrificial layer and a side of the bank layer.

8. The display device of claim 1, wherein a portion of a bottom of the bank layer which is disposed in the non-display area is exposed out of the sacrificial layer, and the light emitting layer is disconnected by being not disposed on the exposed portion of the bank layer.

9. The display device of claim 1, wherein a width of the sacrificial layer is smaller than a width of the bank layer located thereon.

10. The display device of claim 1, wherein the sacrificial layer is formed as a protruding structure which is disposed along a perimeter of the display area in the non-display area.

11. The display device of claim 1, wherein the sacrificial layer includes a first sacrificial layer which is formed to surround and close four surfaces of the display area in the non-display area, and a second sacrificial layer which is formed to be spaced apart outwardly from the first sacrificial layer and surround and close four surfaces of the first sacrificial layer.

12. The display device of claim 1, wherein the sacrificial layer is made of a metal or an inorganic material.

13. The display device of claim 1, wherein the sacrificial layer is made of one selected among copper (Cu), molybdenum (Mo), silicon nitride (SiNx), silicon oxide (SiOx), silicon oxynitride (SiON) and aluminum oxide (Al₂O₃).

14. The display device of claim 1, wherein a height of the sacrificial layer is larger than a height of the first electrode and smaller than a height of the bank layer.

15. The display device of claim 1, wherein the first electrode which is disposed in the non-display area surrounds the display area from a plan view.

16. The display device of claim 2, further comprising:
an encapsulation layer sealing an inner side of the bank layer, an end of the encapsulation layer being disposed in the second opening.

17. The display device of claim 16, further comprising:
a first protective layer disposed under the encapsulation layer, and sealing a top of the second electrode, sides of the sacrificial layer and the bank layer and sides of members provided between the sacrificial layer and the base substrate.

18. The display device of claim 17, further comprising:
a second protective layer sealing the encapsulation layer and the first protective layer which is exposed out of the encapsulation layer.

19. A display device comprising:
a base substrate including a display area and a non-display area adjacent to the display area;
a planarization layer on the base substrate;
a plurality of first electrodes on the planarization layer;
at least one sacrificial layer on the first electrode in the non-display area;
a bank layer including a first opening which exposes the first electrode disposed in the display area and a second opening which exposes a part other than the sacrificial layer disposed in the non-display area;
a light emitting layer on a top of the bank layer and the first electrode and the planarization layer which are exposed through the first opening and the second opening; and
a second electrode on the light emitting layer,
wherein the sacrificial layer is formed as a protruding structure which surrounds the display area in the non-display area, and the light emitting layer is disconnected by not being disposed on a side of the sacrificial layer.

20. The display device of claim 19, wherein the light emitting layer is disconnected by not being disposed on a side of the bank layer.

21. The display device of claim 19, wherein a width of the sacrificial layer is smaller than a width of the bank layer located thereon, so that a portion of a bottom of the bank layer is exposed out of the sacrificial layer, and the light emitting layer is disconnected by not being disposed on the exposed portion of the bank layer.

22. The display device of claim 19, further comprising:
an encapsulation layer sealing an inner side of the bank layer, an end of the encapsulation layer being disposed in the second opening.

23. The display device of claim 22, further comprising:
a first protective layer disposed under the encapsulation layer, and sealing a top of the second electrode, sides of the sacrificial layer and the bank layer and sides of members provided between the sacrificial layer and the base substrate.

24. The display device of claim 23, further comprising:
a second protective layer sealing the encapsulation layer and the first protective layer which is exposed out of the encapsulation layer.
